(19) United States
(12) Patent Application Publication
(10) Pub. No.: US 2016/0276568 A1
(43) Pub. Date: Sep. 22, 2016

(54) ENERGY HARVESTING MATTRESS WITH THERMOELECTRIC FABRIC

(71) Applicant: DREAMWELL, LTD., Las Vegas, NV (US)

(72) Inventors: Michael S. DeFranks, Atlanta, GA (US); Michael A. Golin, Atlanta, GA (US)

(21) Appl. No.: 15/072,419

(22) Filed: Mar. 17, 2016

Related U.S. Application Data
(60) Provisional application No. 62/134,156, filed on Mar. 17, 2015.

(51) Int. Cl. H01L 35/32; A47C 27/00; H02N 2/18; A47C 31/00

(52) U.S. Cl. CPC H01L 35/325; A47C 31/00; A47C 27/00; H02N 2/18

(57) ABSTRACT

Energy harvesting mattresses, systems, and methods of cooling mattresses are disclosed herein. In some aspects, the energy harvesting mattress can include a body support having a proximal surface that is configured to support a sleeper and a flexible thermoelectric fabric comprising at least one p-type layer coupled to at least one n-type layer to provide at least one p-n junction. The flexible thermoelectric fabric can be configured to be in thermal communication with the proximal surface of the body support such that when the proximal surface is heated the flexible thermoelectric fabric generates a current.

### CROSS REFERENCE TO RELATED APPLICATIONS

This Non-Provisional application claims the benefit of U.S. Provisional Patent Application Ser. No. 62/134,156 filed on Mar. 17, 2015, which is fully incorporated herein by reference in its entirety.

### BACKGROUND

The present disclosure generally relates to mattress assemblies, specifically to energy harvesting mattress assemblies using thermoelectric fabric.

In order to maintain homeostasis the human body produces thermal and kinetic energy during sleep that is then subsequently dissipated to the environment. Both forms of energy can be harvested through several methods to generate power (e.g., for small electronic devices, trickle charge batteries, and the like.) Current methods for harvesting energy are inefficient and/or cumbersome.

Thermoelectric systems have been employed in attempts to capture energy. For example, an existing design (e.g., WO2014062187 A1) has been noted to use multiple thermoelectric components spaced about the interior of a mattress. The separation between components decreases effectiveness, as the heat transferred to areas without components is not used in generating electricity. An increase in the number of components would decrease mattress comfort as the components featured are not flexible or conforming. The sparse positioning of the components causes a decrease in efficacy in relation to the sleeper's position on the mattress as sleepers must remain in an ideal position above the components in order to generate maximum electricity. The sparse positioning of the components in WO 2014062187 A1, for example, causes a decrease in effectiveness in relation to the sleeper's position on the mattress. Sleepers must remain in an ideal position above the components in order to realize maximum power generation. The rigid nature of the thermoelectric components requires that they be buried deeper into the mattress in order to maintain comfort which further decreases their effectiveness. Moreover, rigid thermoelectric components are expensive to produce thus making them undesirable for mattress applications.

Accordingly, there remains a need for improved systems, devices, and methods of harvesting energy in mattress assemblies. Specifically, systems, devices, and methods that are less costly to produce, more comfortable, more easily integrated, and would provide more well distributed functionality on a large surface such as a mattress are desired.

### SUMMARY

In some aspects, an energy harvesting mattress can include a body support having a proximal surface that is configured to support a sleeper and a flexible thermoelectric fabric comprising at least one p-type layer coupled to at least one n-type layer to provide at least one p-n junction. The flexible thermoelectric fabric can be configured to be in thermal communication with the proximal surface of the body support such that when the proximal surface is heated the flexible thermoelectric fabric generates a current.

In other aspects, an energy harvesting mattress assembly can include a body support having a proximal surface that is configured to support a sleeper and a flexible thermoelectric fabric for harvesting thermal and kinetic energy. The flexible thermoelectric fabric can have at least one p-type layer coupled to at least one n-type layer to provide at least one p-n junction. Furthermore, the flexible thermoelectric fabric can be in thermal communication with the proximal surface of the body support such that when the proximal surface is heated the flexible thermoelectric fabric generates a current, and the flexible thermoelectric fabric can be disposed along the proximal surface of the body support such that when kinetic energy is transferred to the proximal surface of the body support, the flexible energy harvesting fabric generates a current.

The above described and other features are exemplified by the accompanying drawings and detailed description.

### BRIEF DESCRIPTION OF THE SEVERAL VIEWS OF THE DRAWINGS

This disclosure will be more fully understood from the following detailed description taken in conjunction with the accompanying drawings, in which:

FIG. 1 is a side view of an expanded thermoelectric apparatus that can form a flexible thermoelectric fabric;

FIG. 2 is an exemplary thermoelectric apparatus;

FIG. 3 is a side view of an exemplary flexible thermoelectric fabric;

FIG. 4 is a perspective cut-away view of an exemplary mattress assembly that includes a flexible thermoelectric fabric;

FIG. 5 is a cut-away view of an exemplary mattress assembly that includes a flexible thermoelectric fabric;

FIG. 6 is a perspective view of an exemplary flexible thermoelectric fabric;

FIG. 7 is a diagram of a Peltier effect with respect to a flexible thermoelectric fabric; and

FIG. 8 is a diagram of a Seebeck effect with respect to a flexible thermoelectric fabric.

### DETAILED DESCRIPTION

Certain exemplary aspects will now be described to provide an overall understanding of the principles of the structure, function, manufacture, and use of the devices, systems, methods, and/or kits disclosed herein. One or more examples of these aspects are illustrated in the accompanying drawings. Those skilled in the art will understand that the devices, systems, methods, and/or kits disclosed herein and illustrated in the accompanying drawings are non-limiting and exemplary in nature and that the scope of the present invention is defined solely by the claims. The features illustrated or described in connection with any one aspect described may be combined with the features of other aspects. Such modification and variations are intended to be included within the scope of the present disclosure.

Further in the present disclosure, like-numbered components generally have similar features, and thus each feature of each like-numbered component is not necessarily fully elaborated upon. Additionally, to the extent that linear or circular dimensions are used in the description of the disclosed systems, devices, and methods, such dimensions are not intended to limit the types of shapes that can be used in conjunction with such systems, devices, and methods. A person skilled in the art will recognize that an equivalent to such linear and circular dimensions can be determined for any geometric shape. Sizes and shapes of the systems and devices, and the components thereof, can depend at least on the size and shape of the components with which the systems and devices will be used, and the methods and procedures in which the systems and devices will be used.

Flexible thermoelectric fabrics have been developed for use in various applications. For example and without limitation, thermoelectric fabrics are disclosed in U.S. Publication No. 2013/0312806, which is titled “Thermoelectric Apparatus and Applications Thereof” and is hereby incorporated by reference in its entirety. These fabrics can employ the Seebeck effect through a layered p-n junction material to generate electricity from a thermal gradient. Modules of the material may be arranged in series, parallel, or a combination in order to achieve the desired voltage and current ratings. The thermoelectric fabric remains flexible due to its polymeric construction. This allows for retained comfort when placing the layers proximal to a mattress surface, where a sleeper may be generating heat and where the thermal gradient is larger, generating electricity more efficiently. The term “sleeper” generally refers to a user of the mattress, which can include the user's body heat. Thermoelectric fabrics can also cover an entire sleep surface if needed. This can decrease the positional requirements of the sleeper allowing them to move freely in the mattress while still experiencing uniform temperature distribution and energy harvesting (i.e., this can allow for continuous electricity generation). The use of a thermoelectric fabric as means to harvesting thermal and kinetic energy moves the mechanism closer to the body surface, increasing efficiency. The flexible nature of the thermoelectric fabric can allow it to remain unnoticed to the sleeper (i.e., transparent), maintaining comfort while providing improved efficacy.

Flexible, polymer-based thermoelectric fabrics can be constructed through the lamination of doped p- and n-junction polymers separated by an insulating material. These laminated modules can be stacked and arranged in series, parallel or a combination in order to achieve the desired energy harvesting. Polymer based thermoelectric fabrics can be placed nearer the surface of a mattress to increase efficiency of the energy harvesting process.

Flexible thermoelectric fabrics can also be piezoelectric. As used herein, “piezoelectric” and/or “piezoelectric energy harvesting” means the generation of electricity from kinetic motion distributed through the fabric. For example and without limitation, the thermoelectric fabrics produced through the methods of U.S. Publication No. 2013/0312806 also have the benefit of being piezoelectric. This means that they generate electricity from the thermal gradient across the fabric as well as from kinetic motion distributed through the fabric. The combination of thermoelectric and piezoelectric effects dramatically increases efficiency of the energy harvesting process. Placing these materials near the surface of a mattress can generate enough electricity to charge or power external loads, such as small electronic devices including but not limited to alarm clocks, cell phones, sensors and biofeedback devices. Energy expended by a sleeping person could then be harvested and used to generate electricity to power these devices. In some aspects, power generation capabilities of thermoelectric fabrics can achieve at least about 0.2 W/m². Additionally, in some aspects, power generation capabilities of thermoelectric fabrics can achieve at least about 0.8 W/m². Therefore, as one of ordinary skill in the art will understand, assuming a 1.0 m² contact area on a mattress for an average male sleeper, efficiency rates of the described thermoelectric fabric can be enough to charge an external load such as a cell phone. Table 1 illustrates example thermoelectric, piezoelectric, and combined energy generation data for an example thermoelectric fabric according to some aspects of the present disclosure.

TABLE 1
Energy Harvesting

| Thermoelectric | | Piezoelectric | | | |
|---|---|---|---|---|---|
| | Max | | Stroke | Max | Combined |
| ΔT (K) | TE (W/m²) | Hz | (m) | PE (W/m²) | Combined (W/m²) |
| 10 | 0.1 | 1 | 0.00001 | 0.1 | 0.2 |
| 10 | 0.4 | 1 | 0.00001 | 0.4 | 0.8 |

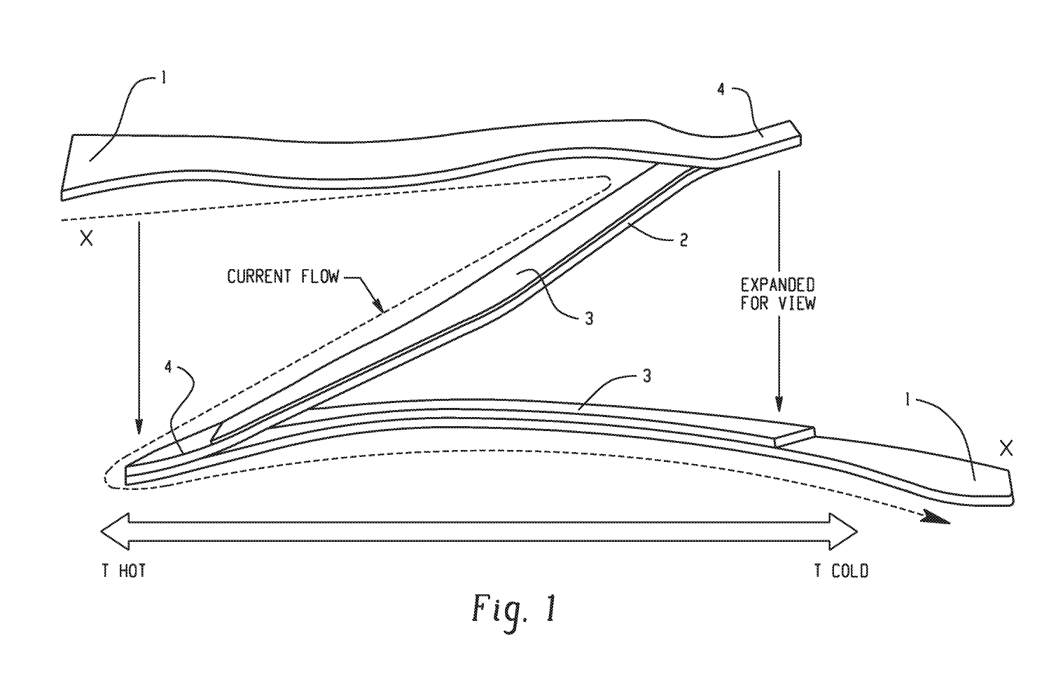

As is explained in greater detail in U.S. Publication No. 2013/0312806, FIG. 1 illustrates an expanded side view of a thermoelectric apparatus that forms example flexible thermoelectric fabrics. The thermoelectric apparatus illustrated in FIG. 1 comprises two p-type layers 1 coupled to an n-type layer 2 in an alternating fashion. The alternating coupling of p-type 1 and n-type 2 layers provides the thermoelectric apparatus a z-type configuration having p-n junctions 4 on opposite sides of the apparatus. Insulating layers 3 are disposed between interfaces of the p-type layers 1 and the n-type layer 2 as the p-type 1 and n-type 2 layers are in a stacked. configuration. As shown, the thermoelectric apparatus provided in FIG. 1 is in an expanded state to facilitate illustration and understanding of the various components of the apparatus. In some aspects, however, the thermoelectric apparatus is not in an expanded state such that the insulating layers 3 are in contact with a p-type layer 1 and an n-type layer 2.

FIG. 1 additionally illustrates the current flow through the thermoelectric apparatus induced by exposing one side of the apparatus to a heat source. Electrical contacts X are provided to the thermoelectric apparatus for application of the thermally generated current to an external load.

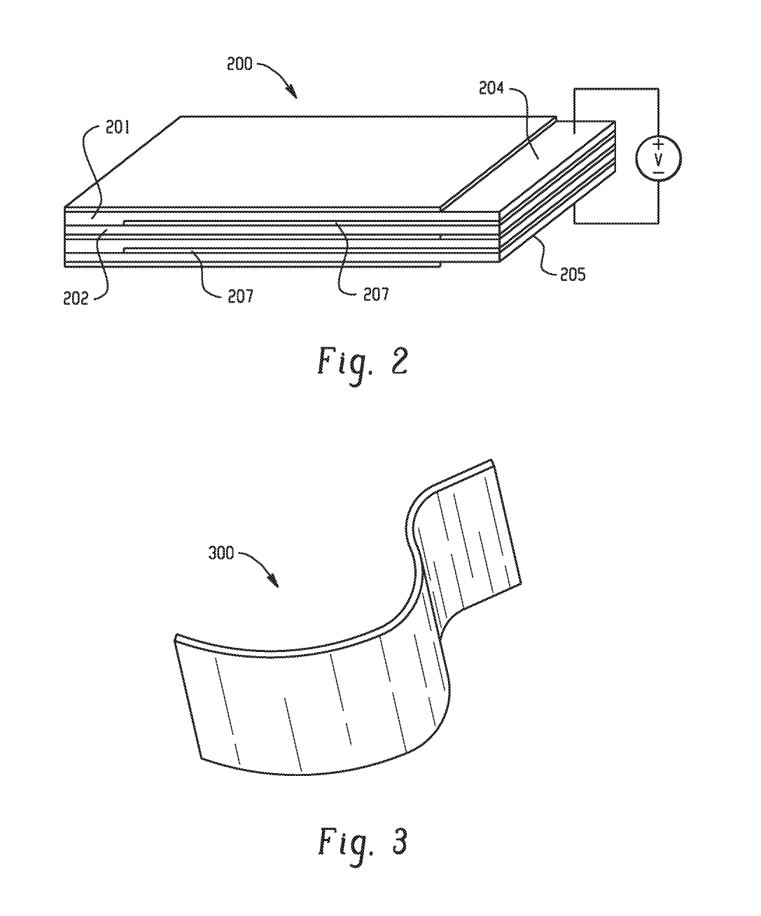

Again as is explained in greater detail in U.S. Publication No. 2013/0312806, FIG. 2 illustrates an example thermoelectric apparatus 200 wherein the p-type layers 201 and the n-type layers 202 are in a stacked configuration. The p-type layers 201 and the n-type layers 202 can be separated by insulating layers 207 in the stacked configuration. The thermoelectric apparatus 200 can be connected to an external load by electrical contacts 204, 205.

FIG. 3 illustrates an example flexible thermoelectric fabric 300. The flexible thermoelectric fabric 300 can comprise a thermoelectric apparatus as described above with respect to FIGS. 1-2 such that the apparatus forms a fabric that is capable of bending easily without breaking. As such, in some aspects, the flexible thermoelectric fabric can comprise at least one p-type layer coupled to at least one n-type layer to provide a p-n junction, and an insulating layer at least partially disposed between the p-type layer and the n-type layer, the p-type layer comprising a plurality of carbon nanoparticles and the n-type layer comprising a plurality of n-doped carbon nanoparticles. In some aspects, carbon nanoparticles of the p-type layer are p-doped and carbon nanoparticles of the n-type layer are n-doped. In some aspects, a p-type layer of a flexible thermoelectric fabric or apparatus can further comprise a polymer matrix in which the carbon nanoparticles are disposed. In some aspects, an n-type layer further comprises a polymer matrix in which the n-doped carbon nanoparticles are disposed. In some aspects, p-type layers and n-type layers of a flexible thermoelectric fabric or apparatus described herein are in a stacked configuration.

In some aspects, carbon nanoparticles of a p-type layer comprise fullerenes, carbon nanotubes, or mixtures thereof In some aspects, carbon nanotubes can comprise single-walled carbon nanotubes (SWNT), multi-walled carbon nanotubes (MWNT), as well as p-doped single-walled carbon nanotubes, p-doped multi-walled carbon nanotubes or mixtures thereof N-doped carbon nanoparticles can comprise fullerenes, carbon nanotubes, or mixtures thereof In some aspects, n-doped carbon nanotubes can also comprise single-walled carbon nanotubes, multi-walled carbon nanotubes, or mixtures thereof.

In some aspects, a p-type layer and/or n-type layer can further comprise a polymeric matrix in which the carbon nanoparticles are disposed. Any polymeric material not inconsistent with the objectives of the present invention can be used in the production of a polymeric matrix. In some aspects, a polymeric matrix comprises a fluoropolymer including, but not limited to, polyvinyl fluoride (PVF), polyvinylidene fluoride (PVDF), polytetrafluoroethylene (PTFE), or mixtures or copolymers thereof. In some aspects, a polymer matrix comprises polyacrylic acid (PAA), polymethacrylate (PMA), polymethylmethacrylate (PMMA) or mixtures or copolymers thereof In some aspects, a polymer matrix comprises a polyolefin including, but not limited to polyethylene, polypropylene, polybutylene or mixtures or copolymers thereof A polymeric matrix can also comprise one or more conjugated polymers and can comprise one or more semiconducting polymers.

As a person of ordinary skill will understand, the “Seebeck coefficient” of a material is a measure of the magnitude of an induced thermoelectric voltage in response to a temperature difference across that material. A p-type layer, in some aspects, can have a Seebeck coefficient of at least about 3 μV/K at a temperature of 290° K. In some aspects, a p-type layer has a Seebeck coefficient of at least about 5 μV/K at a temperature of 290° K. In some aspects, a p-type layer has a Seebeck coefficient of at least about 10 μV/K at a. temperature of 290° K. In some aspects, a p-type layer has a Seebeck coefficient of at least about 15 μV/K or at least about 20 μV/K at a temperature of 290° K. In some aspects, a p-type layer has a Seebeck coefficient of at least about 30 μV/K at a temperature of 290° K. A p-type layer, in some aspects, has a Seebeck coefficient ranging from about 3 μV/K to about 35 μV/K at a temperature of 290° K. In some aspects, a p-type layer has Seebeck coefficient ranging from about 5 μV/K to about 35 μV/K at a temperature of 290° K. In some aspects, a p-type layer has Seebeck coefficient ranging from about 10 μV/K to about 30 μV/K at a temperature of 290° K. As described herein, in some aspects, the Seebeck coefficient of a p-type layer can be varied according to carbon nanoparticle identity and loading. In some aspects, for example, the Seebeck coefficient of a p-type layer is inversely proportional to the single-walled carbon nanotube loading of the p-type layer.

Similarly, an n-type layer can have a Seebeck coefficient of at least about −3 μV/K at a temperature of 290° K. In some aspects, an n-type layer has a Seebeck coefficient at least about −5 μV/K at a temperature of 290° K. In some aspects, an n-type layer has a Seebeck coefficient at least about −10 μV/K at a temperature of 290° K. In some aspects, an n-type layer has a Seebeck coefficient of at least about −15 pV/K or at least about −20 μV/K at a temperature of 290° K. In some aspects, an n-type layer has a Seebeck coefficient of at least about −30 μV/K at a temperature of 290° K. An n-type layer, in some aspects, has a Seebeck coefficient ranging from about −3 μV/K to about −35 μV/K at a temperature of 290° K. In some aspects, an n-type layer has Seebeck coefficient ranging from about −5 μV/K to about −35 μV/K. at a temperature of 290° K. In some aspects, an n-type layer has Seebeck coefficient ranging from about −10 to about −30 μV/K at a temperature of 290° K. In sonic aspects, the Seebeck coefficient of an n-type layer can be varied according to n-doped carbon nanoparticle identity and loading. in some aspects, for example, the Seebeck coefficient of an n-type layer is inversely proportional to the carbon nanoparticle loading of the n-type layer.

As described herein and in U.S. Publication No. 2013/0312806, in some aspects the flexible thermoelectric fabric can include an insulating layer. An insulating layer can comprise one or more polymeric materials. Any polymeric material not inconsistent with the objectives of the present invention can be used in the production of an insulating layer. In sonic aspects, an insulating layer comprises polyacrylic acid (PAA), polymethacrylate (PMA), polymethylmethacrylate (PMMA) or mixtures or copolymers thereof. In some aspects, an insulating layer comprises a polyolefin including, but not limited to polyethylene, polypropylene, polybutylene or mixtures or copolymers thereof In sonic aspects, an insulating layer comprises PVDF. An insulating layer can have any desired thickness not inconsistent with the objectives of the present invention. In some aspects, an insulating layer has a thickness of at least about 50 nm. In some aspects, an insulating layer has a thickness ranging from about 5 nm to about 50 μm. Additionally, an insulating layer can have any desired length not inconsistent with the objectives of the present invention. In some aspects, an insulating layer has a length substantially consistent with the lengths of the p-type and n-type layers between which the insulating; layer is disposed. That is, in some aspects, an insulating layer, p-type layer, and/or n-type layer can have a length of at least about 1 μm, In some aspects, an insulating layer, p-type layer, and/or n-type layer can have a length ranging from about 1 μm to about 500 mm.

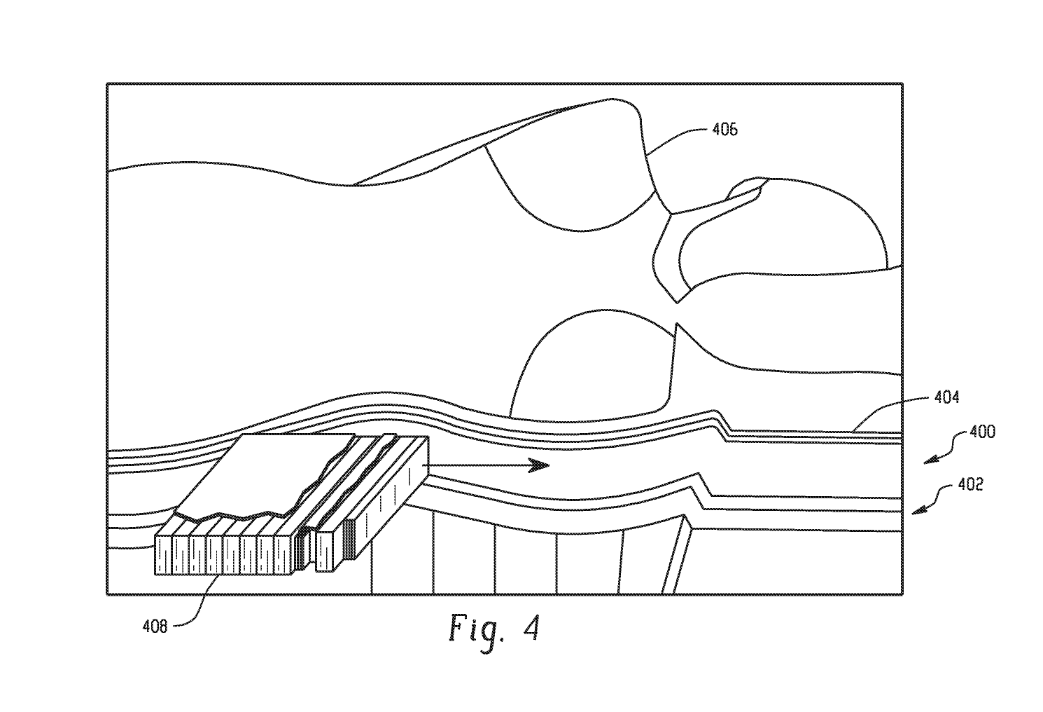

In use, the flexible thermoelectric fabric can be incorporated into a mattress assembly. In so doing, the mattress assembly can be configured to be a temperature control mattress and, additionally or alternatively, can be configured to produce an electric charge. FIG. 4 illustrates an example mattress assembly 400 having a body support 402. The body support 402 has a proximal surface 404 that can support a body 406. The body 406, as shown, can be a human body and the body support 402 can be configured to support the body in a prone, supine, semi-supine, sitting, or any other position so long as the body support 402 supports some portion of the body.

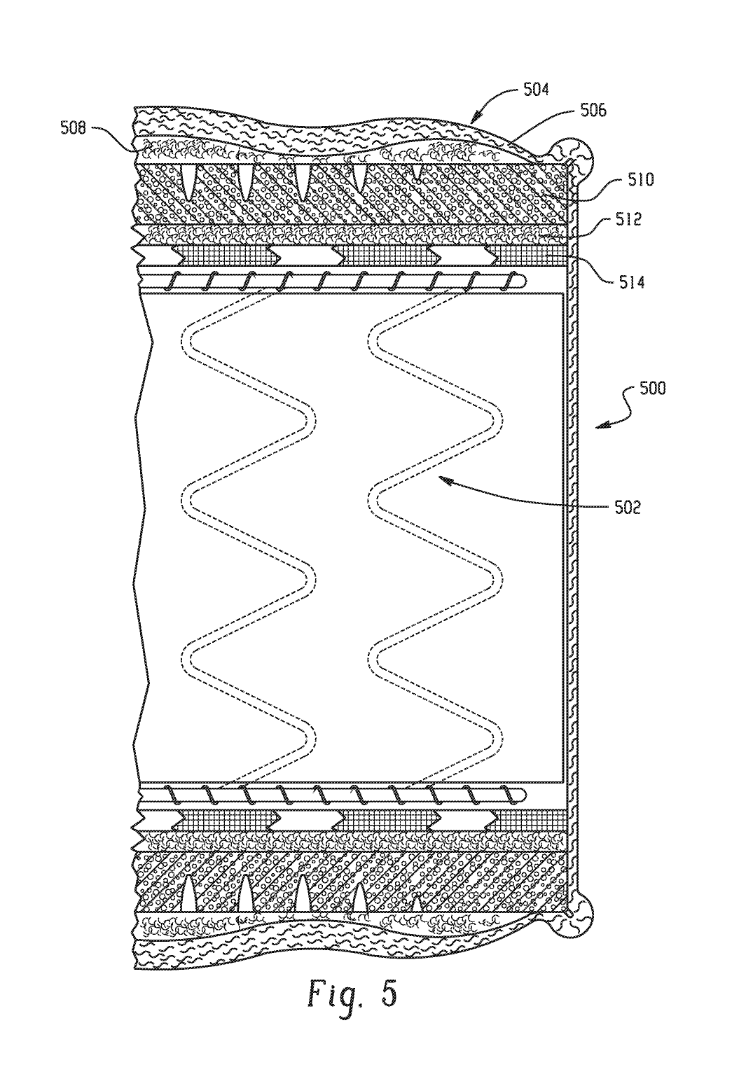

FIG. 5 illustrates an example mattress assembly 500. As shown, the mattress assembly 500 can have an inner support 502 and a body support surface 504. In some aspects, the inner support 502 can be any of a spring, foam, air, or any other core support structure known in the art. The body support surface 504 can, as shown, include a variety of layers 506, 508, 510, 512, 514. The layers can be formed of any support material including foams, gels, fabrics, down feathers, or any other known support material. Additionally, the layers 506, 508, 510, 512, 514 can be configured to allow heat to transfer from the proximal surface or proximal most layer 506 to the distal most layer 514. As such, a flexible thermoelectric fabric can be disposed between any of layers 506, 508, 510, 512, 514. Alternatively and/or additionally, any of the layers 506, 508, 510, 512, 514 can be formed of an example flexible thermoelectric fabric in accordance with the disclosures made herein. For example, layer 506 can be a decorative quilt mattress topper. In some aspects, the quilt topper 506 can be formed of a flexible thermoelectric fabric.

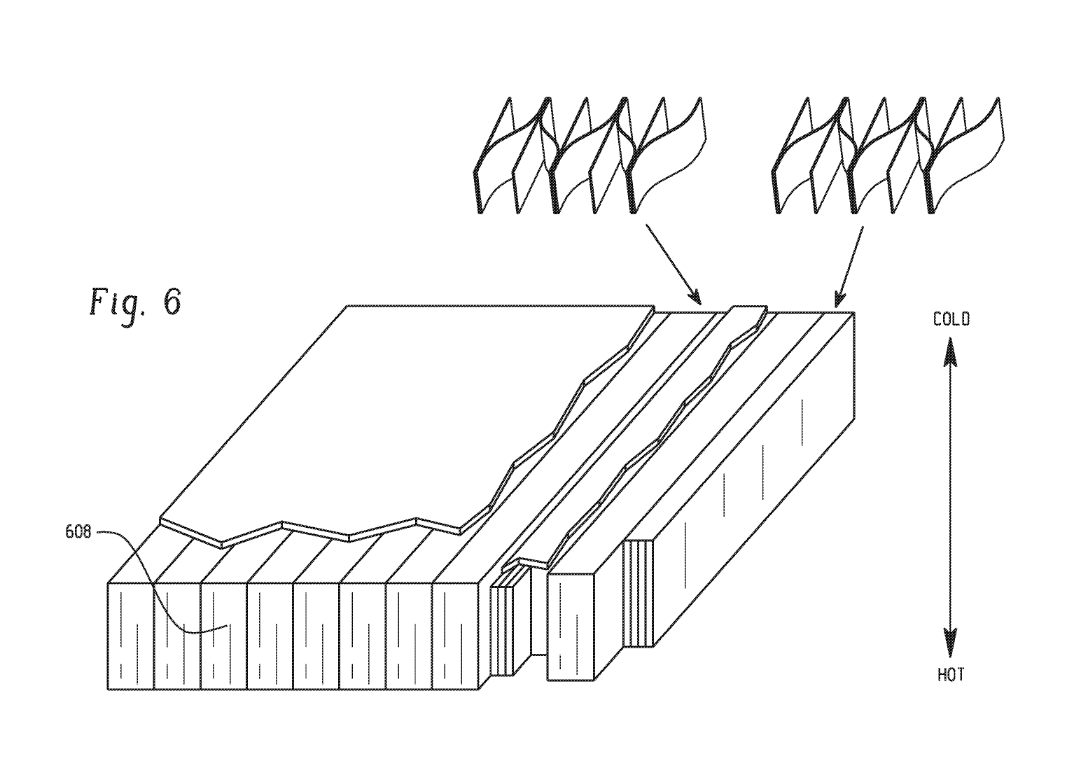

As shown in FIG. 6, the flexible thermoelectric fabric 608 can be formed of stacked p-layers, n-layers, and insulation layers, as is described above. As such, the flexible thermoelectric fabric 608 can be configured to utilize the Peltier effect to cool a portion of the mattress assembly and/or the Seebeck effect to harvest energy from the mattress assembly. As used herein and as a person of ordinary skill will understand, the “Peltier effect” means the presence of heating or cooling at an electrified junction of two different conductors. Further, as a person of ordinary skill will understand, the “Seebeck effect” means an induced thermoelectric voltage in response to a temperature difference across a material.

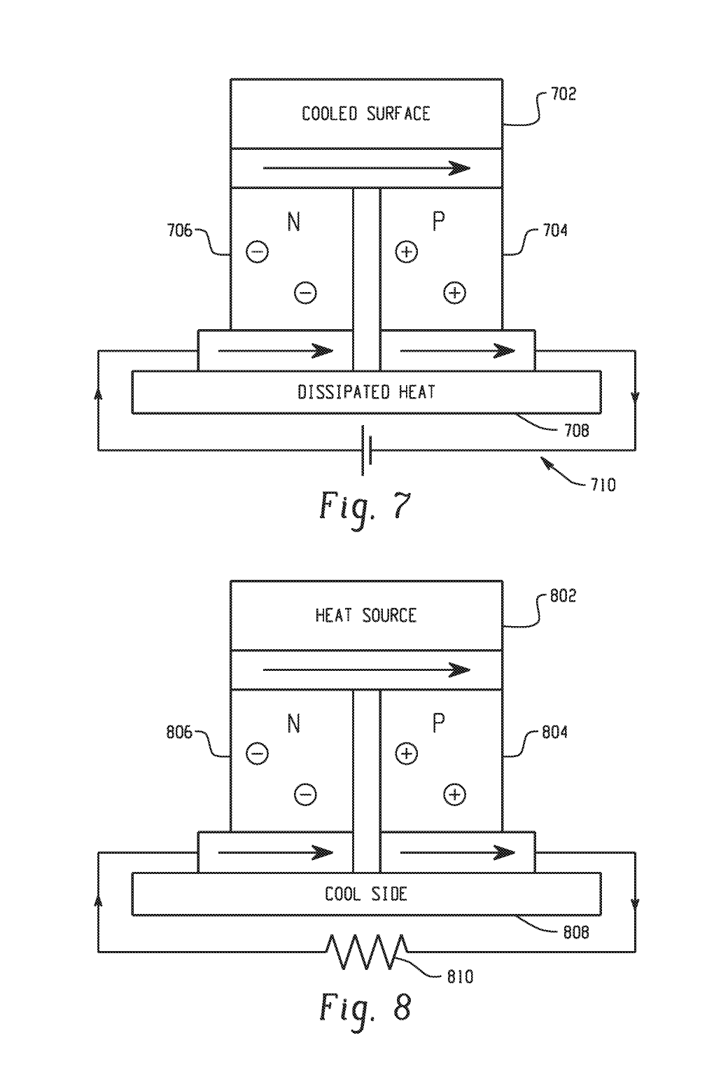

FIG. 7 illustrates an example diagram of the Peltier effect, which can result in cooling of the body support surface when the flexible thermoelectric fabric is disposed such that it is in thermal communication with the proximal surface of the body support. In this manner, the top-most layer 702 of the fabric is cooled as charge moves through the p-layer 704 and n-layers 706 accordingly. As such, heat is dissipated along a bottom-most surface 708 of the fabric as the p-layer(s) and n-layer(s) are connected by a circuit 710.

FIG. 8 illustrates an example diagram of the Seebeck effect, which can result in energy harvesting, i.e., the generation of an electrical voltage when the flexible fabric is heated at the proximal surface of the body support, such as when a human lays on the body support and transfers its body heat into the proximal surface of the body support. As shown, the top-most surface 802 of the fabric is exposed to a heat source—e.g., a sleeper's body heat—and the bottom-most surface 808 is at a temperature that is cooler than the top-most layer 802. Voltage is generated by the system when the p-layers 804 are connected to the n-layers 806 with a load resistor 810.

Thus, in some aspects, either to maximize temperature regulation of the sleeping surface (i.e., the proximal surface of the body support) or to maximize a current generated by the flexible fabric, the fabric can be disposed along an entire proximal surface of a mattress. As was described above, for example, a mattress topper can be formed entirely of flexible thermoelectric fabric. Alternatively, the fabric can be strategically located along portions of the fabric so as to maximize thermal communication between the proximal surface and the fabric. That is, the fabric can be placed in any manner that is consistent with absorbing a desired and/or optimal amount of body heat from a body. Additionally, the flexible nature of the example thermoelectric fabrics provide various advantages as described herein. For example, they are less costly to produce, more comfortable, more easily integrated and would provide more well distributed functionality on a large surface such as a mattress. The above disclosure solves positional and comfort issues by allowing for uniform thermal control decreasing hot spots or cold spots. This in turn also allows the sleeper to move freely without sensing changes in the cooling/heating system efficiency and furthermore, allows for the thermoelectric system to be near the surface of the mattress for greater efficiency.

With respect to the above description, it is to be realized that the optimum composition for the parts of the invention, to include variations in components, materials, size, shape, form, function, and manner of operation, assembly and use, are deemed readily apparent to one skilled in the art, and all equivalent relationships to those illustrated in the examples and described in the specification are intended to be encompassed by the present invention. Therefore, the foregoing is considered as illustrative only of the principles of the invention. Further, various modifications may be made of the invention without departing from the scope thereof, and it is desired, therefore, that only such limitations shall be placed thereon as are set forth in the appended claims.

What is claimed is:

1. An energy harvesting mattress, comprising:
a body support having a proximal surface that is configured to support a sleeper; and
a flexible thermoelectric fabric comprising at least one p-type layer coupled to at least one n-type layer to provide at least one p-n junction,
wherein the flexible thermoelectric fabric is configured to be in thermal communication with the proximal surface of the body support such that when the proximal surface is heated the flexible thermoelectric fabric generates a current.

2. The mattress of claim 1, wherein the flexible thermoelectric fabric is configured to apply the generated current to an external load.

3. The mattress of claim 1, wherein the flexible thermoelectric fabric is further configured for piezoelectric energy harvesting.

4. The mattress of claim 1, wherein the flexible thermoelectric fabric generates at least about 0.2 W/m².

5. The mattress of claim 1, wherein the flexible thermoelectric fabric is disposed along the entire proximal surface of the body support.

6. The mattress of claim 1, wherein the flexible thermoelectric fabric comprises plurality of p-type layers coupled to a plurality of n-type layers to provide a plurality of p-n junctions.

7. The mattress of claim 6, wherein the plurality of p-type layers have a Seebeck coefficient of at least about 3 μV/K at 290° K.

8. The mattress of claim 6, wherein the plurality of n-type layers have a Seebeck coefficient of at least about −3 μV/K at 290° K.

9. The mattress of claim 1, wherein the flexible thermoelectric fabric further comprises at least one insulating layer.

10. The mattress of claim 1, wherein the flexible thermoelectric fabric comprises a plurality of carbon nanotubes.

11. A mattress assembly, comprising:
a body support having a proximal surface that is configured to support a sleeper; and
a flexible thermoelectric fabric for harvesting thermal and kinetic energy having at least one p-type layer coupled to at least one n-type layer to provide at least one p-n junction,
wherein the flexible thermoelectric fabric is in thermal communication with the proximal surface of the body support such that when the proximal surface is heated the flexible thermoelectric fabric generates a current, and the flexible thermoelectric fabric is disposed along the proximal surface of the body support such that when kinetic energy is transferred to the proximal surface of the body support, the flexible energy harvesting fabric generates a current.

12. The mattress of claim 11, wherein the flexible thermoelectric fabric is configured to apply the generated current to an external load.

13. The mattress of claim 11, wherein the flexible thermoelectric fabric generates at least about 0.2 W/m².

14. The mattress of claim 11, wherein the flexible thermoelectric fabric is disposed along the entire proximal surface of the body support.

15. The mattress of claim 11, wherein the flexible thermoelectric fabric comprises plurality of p-type layers coupled to a plurality of n-type layers to provide a plurality of p-n junctions.

16. The mattress of claim 15, wherein the plurality of p-type layers have a Seebeck coefficient of at least about 3 μV/K at 290° K.

17. The mattress of claim 15, wherein the plurality of n-type layers have a Seebeck coefficient of at least about −3 μV/K at 290° K.

18. The mattress of claim 11, wherein the flexible thermoelectric fabric further comprises at least one insulating layer.

19. The mattress of claim 11, wherein the flexible thermoelectric fabric comprises a plurality of carbon nanotubes.

20. The mattress of claim 19, wherein a portion of the carbon nanotubes are single-walled carbon nanotubes.
